(19) United States
(12) Patent Application Publication
(10) Pub. No.: US 2017/0115556 A1
(43) Pub. Date: Apr. 27, 2017

(54) MASK MANUFACTURING METHOD AND SEMICONDUCTOR DEVICE MANUFACTURING METHOD USING THE SAME

(71) Applicant: Samsung Electronics Co., Ltd., Suwon-si (KR)

(72) Inventors: Woo-seok Shim, Osan-si (KR); Wenqing Liang, Seongnam-si (KR)

(21) Appl. No.: 15/299,558

(22) Filed: Oct. 21, 2016

(30) Foreign Application Priority Data
Oct. 22, 2015 (KR) 10-2015-0147545

(51) Int. Cl. G03F 1/36; G06F 17/50

(52) U.S. Cl. CPC G03F 1/36; G06F 17/5081; G06F 2217/12

(57) ABSTRACT

A mask manufacturing method and a semiconductor device manufacturing method are provided. The methods form a plurality of dummy patterns without any change in hierarchical structure to reduce a turn-around time (TAT) and a performance of a system. The mask manufacturing method includes designing a layout of a main pattern, performing integrated optical proximity correction (OPC) on the layout, delivering design data, obtained through the integrated OPC, as mask tape-out (MTO) design data, preparing mask data based on the MTO design data, and exposing a substrate for a mask, based on the mask data, wherein the performing of the integrated OPC includes generating a dummy pattern in a state of maintaining hierarchical structure.

### CROSS-REFERENCE TO RELATED APPLICATION

This application claims the benefit of priority under 35 U.S.C. §119 to Korean Patent Application No. 10-2015-0147545, filed on Oct. 22, 2015, in the Korean Intellectual Property Office, the disclosure of which is incorporated herein in its entirety by reference.

### BACKGROUND

The disclosed embodiments relate to a mask manufacturing method, for example, aspects of embodiments are related to a mask manufacturing method using optical proximity correction (OPC) and a semiconductor device manufacturing method using the same.

In a semiconductor manufacturing process, a lithography process using a mask may be performed for forming a pattern on a semiconductor substrate such as a wafer or the like. The mask may be simply defined as a pattern transfer artifact where a pattern including an opaque material is formed on a transparent base material. To briefly describe a mask manufacturing process, a desired circuit may be first designed, a layout of the circuit may be designed, and design data obtained through OPC may be delivered as mask tape-out (MTO) design data. Subsequently, a mask data preparation (MDP) process may be performed based on the MTO design data, and a mask may be manufactured by performing a front-end-of-line (FEOL) process and a back-end-of-line (BEOL) process. The FEOL process, for example, may include an exposure process for mask, a chemical treatment process, and a metrology process. The exposure process for mask may use an E-beam or a laser. The BEOL may include a defect inspection process, a defect repair process, and a pellicle coating process.

### SUMMARY

The disclosed embodiments provide a mask manufacturing method and a semiconductor device manufacturing method, which form a plurality of dummy patterns without any change in hierarchical structure, thereby reducing a turn-around time (TAT) and a performance of a system.

According to an aspect of the inventive concept, there is provided a method that includes steps of designing a layout of a main pattern, performing integrated optical proximity correction (OPC) on the layout, obtaining design data from the result of the integrated OPC, delivering the design data as mask tape-out (MTO) design data, preparing mask data, based on the MTO design data, and exposing a substrate to form a mask, based on the mask data, wherein the performing of the integrated OPC comprises generating a dummy pattern in a state of maintaining hierarchical structure.

The performing of the integrated OPC may include steps of analyzing a structure of the layout, separating templates, based on the analysis, generating the dummy pattern after separating the templates, generating a sub-resolution assist feature (SRAF), and performing OPC on the templates.

The dummy pattern may be generated in a state of maintaining the hierarchical structure in each of the templates. The dummy pattern and the SRAF may be generated in the same template. The templates may be distinguished from and separated from each other, based on an influence range of the main pattern.

The main pattern may be a pattern corresponding to a circuit pattern of a semiconductor device, the dummy pattern may be an auxiliary pattern for preventing a patterning error of the circuit pattern and may be formed in the semiconductor device, and the SRAF may be an auxiliary pattern for compensating for an OPC deviation caused by a density difference between patterns and may not be formed in the semiconductor device. The performing of the integrated OPC may include a step of receiving data corresponding to the layout, which does not include the dummy pattern.

The method may further include a step, after the designing of the layout, performing a design rule check (DRC), wherein the performing of the DRC may include steps of proceeding to the performing of the integrated OPC when a predetermined reference is satisfied, and proceeding to the designing of the layout when the predetermined reference is not satisfied.

The method may further include, after the performing of the integrated OPC, performing OPC verification, wherein the performing of the OPC verification may include steps of proceeding to the delivering of the design data as the MTO design data when a predetermined reference is satisfied, and proceeding to the performing of the integrated OPC when the predetermined reference is not satisfied. The method may further include a step of exposing a semiconductor substrate using the mask to form a semiconductor device.

According to certain embodiments, a method of manufacturing a semiconductor device may include steps of designing a layout of a main pattern, receiving data corresponding to the layout, performing integrated optical proximity correction (OPC) including generating a dummy pattern in a state of maintaining a hierarchical structure and generating design data, delivering the design data as mask tape-out (MTO) design data, preparing mask data, based on the MTO design data, exposing a substrate to form a mask, based on the mask data, and forming a semiconductor device through a lithography process using the mask.

The performing of the integrated OPC may include steps of analyzing a structure of the layout to separate templates, generating the dummy pattern and a sub-resolution assist feature (SRAF) in each of the templates, and performing OPC on the templates. The dummy pattern and the SRAF may be generated in the same template.

The method may further include steps, after the designing of the layout, performing design rule check (DRC), and after the performing of the integrated OPC, performing OPC verification, wherein the performing of the DRC may include proceeding to the performing of the integrated OPC or the designing of the layout according to whether a predetermined reference is satisfied, and the performing of the OPC verification may include proceeding to the delivering of the design data as the MTO design data or the performing of the integrated OPC according to whether the predetermined reference is satisfied.

According to certain embodiments, a method includes steps of designing a layout of main patterns of a mask, determining the layout into a plurality of templates based on the structure of the layout, generating dummy patterns in the respective templates, performing optical proximity correction in the patterns of the respective templates, delivering mask tape-out design data based on the result of the optical proximity correction, and forming a photomask with the mask tape-out design data.

The method may further include steps of exposing a substrate using the photomask to form a photoresist pattern on the substrate, etching the substrate using the photo resist pattern as an etching mask, and dividing the substrate into a plurality of chips. The method may further include steps of forming a semiconductor package with a first chip of the plurality of chips, and mounting the package on a board to form an electronic device. The method may further include steps of generating sub resolution assist features in the respective templates before performing the optical proximity correction. The method may further include a step of performing a design rule check before the determining the layout into the plurality of templates. The determining the layout into the plurality of templates may include considering an influence range between adjacent patterns.

### BRIEF DESCRIPTION OF THE DRAWINGS

Exemplary embodiments of the inventive concept will be more clearly understood from the following detailed description taken in conjunction with the accompanying drawings in which:

FIG. 1 is a flowchart of a mask manufacturing method according to an embodiment;

FIG. 2 is a flowchart of a mask manufacturing method according to an embodiment;

FIG. 3 is a flowchart illustrating in detail integrated OPC in the mask manufacturing method of FIG. 1;

FIGS. 4A and 4B are a layout for describing a reason of forming a dummy pattern;

FIGS. 5A and 5B are a conceptual diagram for describing a relationship of a hierarchical structure and a method of forming a dummy pattern;

FIGS. 6 and 7A to 7C are conceptual diagrams for describing a concept of a template;

FIGS. 8 and 9 are layouts illustrating a method of generating a sub-resolution assist feature (SRAF);

FIGS. 10A to 10C are a conceptual diagram illustrating a result obtained by applying a hierarchical dummy pattern generating method according to an embodiment and a result obtained by applying a dummy pattern generating method generating dummy patterns before defining templates;

FIGS. 11A and 11B are a template illustrating a result obtained by applying a hierarchical dummy pattern generating method according to an embodiment and a result obtained by applying a dummy pattern generating method generating dummy patterns before defining templates; and

FIG. 12 is a flowchart of a semiconductor device manufacturing method according to an embodiment.

### DETAILED DESCRIPTION

As used herein, the term “and/or” includes any and all combinations of one or more of the associated listed items. Expressions such as “at least one of” when preceding a list of elements, modify the entire list of elements and do not modify the individual elements of the list.

Hereinafter, exemplary embodiments will be described in detail with reference to the accompanying drawings. Embodiments of the inventive concept are provided for fully conveying the concept of the inventive concept to those skilled in the art. The inventive concept may be embodied in many different forms and should not be construed as being limited to the embodiments set forth herein; these example embodiments are just that—examples—and many implementations and variations are possible that do not require the details provided herein. It should also be emphasized that the disclosure provides details of alternative examples, but such listing of alternatives is not exhaustive. Furthermore, any consistency of detail between various examples should not be interpreted as requiring such detail—it is impracticable to list every possible variation for every feature described herein. The language of the claims should be referenced in determining the requirements of the invention.

It will be understood that, although the terms first, second, third etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section, for example as a naming convention. Thus, a first element, component, region, layer or section discussed below in one section of the specification could be termed a second element, component, region, layer or section in another section of the specification or in the claims without departing from the teachings of the present invention. In addition, in certain cases, even if a term is not described using “first,” “second,” etc., in the specification, it may still be referred to as “first” or “second” in a claim in order to distinguish different claimed elements from each other.

In this disclosure below, when an element is described as being connected to another element, the element may be directly connected to the other element, but a third element may be disposed therebetween. When an element is referred to as being ‘on’ another element, it may be directly on the other element, or intervening elements may also be present. Structures or sizes of elements illustrated in the accompanying drawings and an interval between the elements may be exaggerated for clarity of the specification, and a portion irrelevant to description is omitted. Like reference numerals refer to like elements throughout. Terms used herein are described for the purpose of describing the inventive concept, and are not described for limiting a meaning or limiting the spirit and scope of the inventive concept defined by claims.

As used herein, a semiconductor device may refer to a device such as a semiconductor chip (e.g., memory chip and/or logic chip formed on a die), a stack of semiconductor chips, a semiconductor package including one or more semiconductor chips stacked on a package substrate, or a package-on-package device including a plurality of packages. These devices may be formed using ball grid arrays, wire bonding, through substrate vias, or other electrical connection elements, and may include memory devices such as volatile or non-volatile memory devices.

An electronic device, as used herein, may refer to these semiconductor devices, but may additionally include products that include these devices, such as a memory module, memory card, hard drive including additional components, or a mobile phone, laptop, tablet, desktop, camera, or other consumer electronic device, etc.

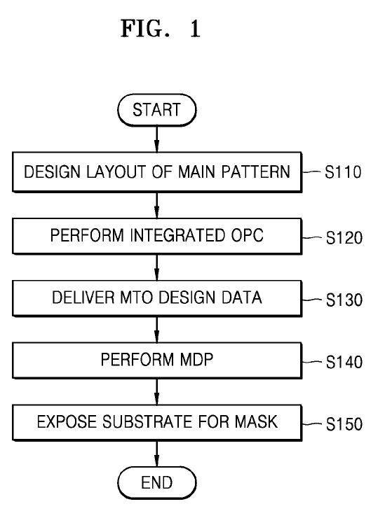

FIG. 1 is a flowchart of a mask manufacturing method according to an embodiment.

Referring to FIG. 1, first, a layout of a main pattern may be designed in operation S110. Generally, in a case where a circuit designer designs a circuit for a semiconductor device, a designed circuit may be implemented in a mask form by performing designing of a layout of the designed circuit. Here, the layout may be a physical mark for transferring the designed circuit onto a wafer, and the main pattern may correspond to an interconnection and a circuit directly related to an operation of the semiconductor device. When a designing operation for a layout of a plurality of the main patterns is completed, it may be considered that a basic layout operation for the operation of the semiconductor device is completed.

Generally, a layout of main patterns may be formed in a state where hierarchical structure is high or good. Here, the hierarchical structure being high or good denotes that patterns are easily distinguished from each other. As a circuit structure becomes simpler, the hierarchical structure may become higher, and as the circuit structure becomes complicated, the hierarchical structure may become lower. Therefore, the layout of the main patterns may be formed in a relatively simple structure, and thus, patterns are easily distinguished from each other. For example, a memory array corresponding to a high-level hierarchical structure may be described as including cells which are repeated in a certain number of rows and columns. A basic memory cell corresponding to a next-level hierarchical structure may be described as including subpixels A and B. Subpixels corresponding to a lowest-level hierarchical structure may be depicted in a geometrical rectangle or polygon. As another example, circuits corresponding to a front-end-of-line (FEOL) operation of forming a transistor may be designed as relatively simple layouts and thus may have a high-level hierarchical structure, but circuits corresponding to a back-end-of-line (BEOL) operation of forming a metal wiring may be designed as complicated layouts and thus may have a low-level hierarchical structure.

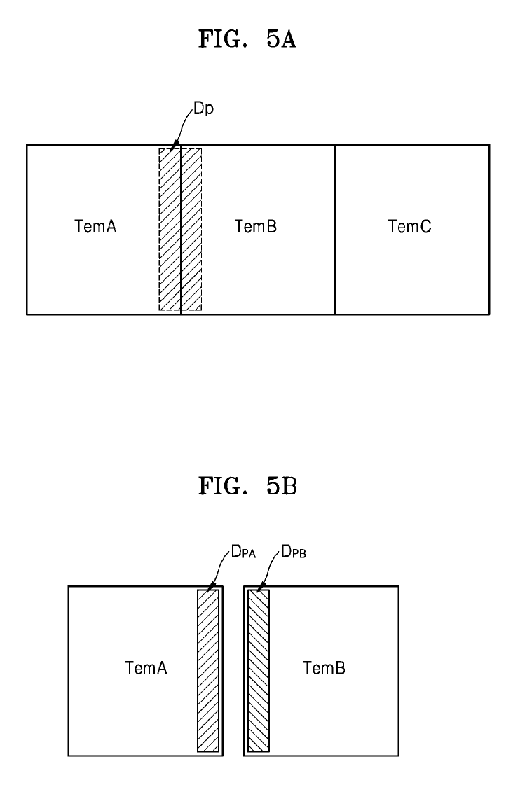

Subsequently, in operation S120, integrated optical proximity correction (OPC) may be performed for a layout of a pattern. Here, the performing of the integrated OPC denotes that an operation of generating a dummy pattern and OPC (hereinafter referred to as basic OPC for distinguishing from the integrated OPC) are integratedly performed together. As described above, a basic layout for a semiconductor device may be completed through designing of a layout of main patterns. However, in a basic layout, non-uniformity of a pattern density is caused by spaces between main patterns and causes a pattern defect in performing a lithography process. Therefore, the spaces between the main patterns may be filled with dummy patterns so as to prevent a pattern defect, and the dummy patterns may be patterns irrelevant to an operation of a semiconductor device. An operation of generating dummy patterns will be described in detail with reference to FIG. 5.

The dummy patterns may be generated by using a rule based pattern generating method independently from the basic OPC and may be implemented by using a design rule check (DRC) tool. However, an operation of generating dummy patterns by using the DRC tool may be a main cause of deforming a hierarchical structure of a main pattern, for example, the DRC tool may badly degrade or lower a hierarchical structure.

As the kinds of semiconductor devices become complicated and a degree of integration increases, the amount of data and runtime of a dummy pattern generation operation and a subsequent operation thereof increase exponentially. For example, in a case where the dummy pattern generation operation is performed by using the DRC tool, and then a layout verification operation such as layout versus schematic (LVS) and DRC is performed, as a capacity of a semiconductor chip increases, and as a density of the semiconductor chip increases, a hierarchical structure may become more complex, and the number of calculation operations for a subsequent operation increases exponentially. OPC and Optical Rule Check (ORC) may be performed after the layout verification operation. In this case, the increases in complexity of a hierarchical structure and the increase of the number of calculation operations cause increases in runtime of the OPC and the ORC and graphic design system (GDS) or open artwork system interchange standard (OASIS) data capacity, causing increases in time, data, and various costs in a mask manufacturing process.

As described above, a hierarchical structure of a layout of a main pattern may be maintained as a relatively high hierarchical structure in terms of a design structure, and thus, the incidence of an increase in runtime or GDS data capacity is not large in OPC of a subsequent operation. For example, when the OPC is performed by using data of only a layout of a main pattern, the incidence of an increase in runtime or GDS data capacity is not large. However, when an operation of generating dummy patterns is performed by using the DRC tool, a hierarchical structure is damaged in a designing operation, causing a low hierarchical structure corresponding to a flat level. As described above, a hierarchical structure of a layout of a pattern is deformed to a low hierarchical structure in the operation of generating the dummy patterns, and for this reason, a runtime and a GDS data capacity rapidly increase in the OPC operation of the subsequent operation.

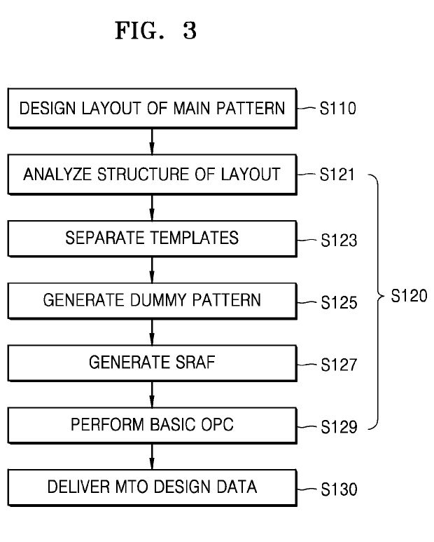

However, in the mask manufacturing process, in order to improve process proximity correction (PPC) and OPC, an operation of generating dummy patterns corresponding to a position where there is no main pattern or a density is low may be an essential operation and cannot be omitted. Therefore, in the mask manufacturing method according to an embodiment, the dummy pattern generation operation and the basic OPC may be simultaneously performed in performing the integrated OPC, thereby solving a problem where the runtime and GDS data capacity of the OPC increase because a dummy pattern is generated at a flat level by using the DRC tool. Accordingly, time and cost are considerably reduced in a designing operation for a layout of a pattern of a mask. Details of the integrated OPC operation will be described in detail with reference to FIG. 3.

As patterns are getting finer, the patterns are more likely to be affected by the optical proximity effect (OPE) during an exposure process. OPE is an influence between adjacent patterns in an exposure process. OPE is usually caused by optical interferences between adjacent patterns of light. OPE is usually unwanted optical interference. OPC (i.e., the basic OPC) is a method that adjusts a layout of a pattern to prevent the OPE from occurring. Therefore, a layout of a main pattern and a layout of dummy patterns may be corrected through the basic OPC without being used as a pattern in a mask as-is. The basic OPC may be categorized into two operations, and for example, one operation may be rule-based OPC, and the other operation may be simulation-based or model-based OPC.

The rule-based OPC may first manufacture a test mask and may transfer a pattern of the test mask onto a wafer to manufacture a test wafer. Subsequently, a design rule may be determined based on measurement data corresponding to a pattern formed in the test wafer and design data of the test mask. For example, a design rule for determining bias data applied to an operation of designing a layout of a pattern may be determined based on the measurement data and the design data of the test mask. When the design rule is determined, the layout of the pattern may be corrected based on the design rule. The correction may be performed in a computer-aided design (CAD) operation of designing the layout of the pattern. The rule-based OPC may measure test patterns corresponding to all patterns that can be used in actual design, and moreover, since the OPC may be repeated whenever a process is changed, the rule-based OPC may be a relatively time consuming and/or cost increasing process.

The model-based OPC may generate kernels expressing a pattern transfer process with the consideration of the OPE based on a measurement result of a prepared standard test pattern (i.e., a measurement result of a representative pattern), and then perform a simulation to calculate a difference between the patterns of a mask (e.g., a pattern shape of a mask) and the patterns transferred onto a wafer (e.g., a pattern shape on a wafer) based on a process model including the kernels, and then correct a layout of a pattern according to a result of the simulation. The model-based OPC may not measure large-scale test patterns and thus is efficient in time and cost. However, it is difficult for the model-based OPC to faithfully reflect an influence of a density of patterns, shapes of adjacent patterns, or a distance between adjacent patterns.

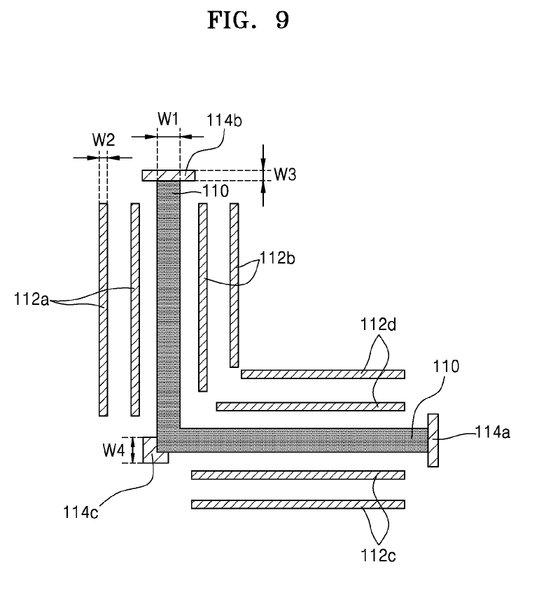

The basic OPC may include a method of adding sub-lithographic features called serifs to corners of a pattern or a method of adding sub-resolution assist features (SRAFs) such as scattering bars, in addition to modification of a layout of a pattern. Here, the serifs may be tetragonal features which are respectively positioned in corners of a pattern, and may sharpen corners of a pattern finally transferred onto a wafer. Also, the serifs may be used in an intersection area for compensating for a distortion factor caused by intersection of two different patterns. The SRAF may be a feature which is formed to have a size less than a resolution of exposure equipment and is not transferred onto a resist layer. For example, the SRAF may not be a pattern which is actually formed on a wafer. When patterns are formed in a high-density area or a low-density area, the patterns may have different diffractions depending on the density of the patterns because of optical characteristics. For this reason, a deviation may occur due to correction of the OPE, for example, in the result of the OPC. The SRAF may be an auxiliary pattern which is introduced for solving an OPC deviation caused by a density difference between patterns. The serif or the SRAF will be described in detail with reference to FIG. 9.

After the integrated OPC is performed, design data obtained through the integrated OPC may be delivered as mask tape-out (MTO) design data in operation S130. Generally, MTO may denote a process of delivering design data of a mask after the basic OPC is completed, to a mask manufacturing process so that a mask is manufactured (e.g., by a mask manufacturing team). Therefore, the MTO design data may denote design data of a mask for which the OPC is completed. The MTO design data may have a graphic data format applied to electronic design automation (EDA) software. For example, the MTO design data may have a data format such as GDS, OASIS, or the like.

After the MTO design data is delivered, mask data preparation (MDP) may be performed in operation S140. The MDP may include format conversion, augmentation, and verification.

The format conversion may be referred to as fracturing and may denote a process that divides MTO design data by areas, and changes the divided MTO design data into a format for an e-beam writer. In the fracturing, data manipulation such as scaling, sizing of data, rotating of data, pattern reflection, and color conversion may be performed.

In the format conversion, data corresponding to a number of systematic errors which occur in an operation of transferring design data to an image on a wafer may be corrected. A data correction process for the systematic errors is referred to as mask process correction (MPC), and for example, may include line width adjustment, referred to as critical dimension (CD) adjustment, and an operation of increasing a degree of precision of a pattern arrangement. Therefore, fracturing contributes to enhancing a quality of a final mask and may be a process that is preferentially performed for MPC. Here, the systematic errors are caused by distortion which occurs in an exposure process, a mask development process, a mask etching process, and a wafer imaging process.

The augmentation may include augmentation of a barcode for mechanical readout, an identifiable label, an aim mark, and a job deck. Here, the job deck may mean generating a text file about a series of instructions such as arrangement information of multi mask files, a reference dose, and an exposure speed or method.

The verification may include automatic verification and manual verification.

After the MDP is performed, exposure may be performed for a substrate for mask in operation S150. The exposure may denote, for example, e-beam writing. Here, the e-beam writing process may be performed in a gray writing method using a multi-beam mask writer (MBMW). Also, the e-beam writing may be performed by using a variable shape beam (VSB) writer. In certain embodiments, the exposure may denote laser exposure.

Data processing may be performed before the exposure process. The data processing is a preprocessing operation for the mask data, and may include grammar check and exposure time prediction for the mask data. Also, after the MDP stage, a process of converting the mask data into pixel data may be performed before the exposure process. The pixel data is data which is directly used in an actual exposure, and may include data about a shape, which is an exposure target, and data about an allocated dose. Here, the data about the shape may be bitmap data obtained by converting shape data (vector data) through rasterization.

After the exposure process, a mask may be formed by performing a series of processes. The series of processes may include, for example, development, etching, cleaning, and baking. Also, the series of processes may include a pellicle coating process. Here, the pellicle coating process means a process of adhering pellicles for protecting the mask from subsequent pollution during the service life time of the mask and during the delivering process of the mask. Before the pellicle coating process, final cleaning and inspection are performed, during which time it is confirmed that there are no pollution particles or chemical stains on the mask.

As described above, the mask manufacturing method according to the embodiments includes the integrated OPC stage of simultaneously performing a dummy pattern generation operation and the basic OPC, thereby addressing a situation where a runtime and a GDS data capacity largely increase in a subsequent OPC stage because a dummy pattern is generated at a flat level by using the DRC tool. Therefore, the mask manufacturing method according to certain embodiments considerably decreases a series of processes (for example, a TAT of the OPC and the ORC) of manufacturing a mask after a layout of a mask pattern is designed, thereby considerably decreasing the time and cost of a mask manufacturing process and lowering the required performance of a system.

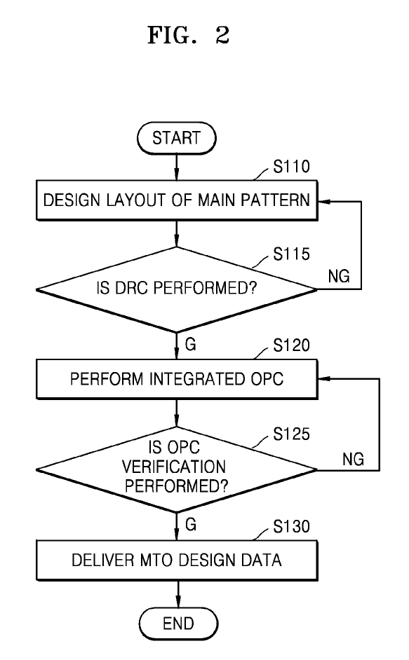

FIG. 2 is a flowchart of a mask manufacturing method according to an embodiment. The details described above with reference to FIG. 1 will be briefly described or omitted.

Referring to FIG. 2, after the operation S110 of performing the layout design for the main pattern, the mask manufacturing method according to an embodiment may perform design rule check (DRC) in operation S115. The DRC may denote an operation of checking whether the designed layout satisfies a design rule. When the layout satisfies the design rule at the DRC (G), the mask manufacturing method may proceed to the integrated OPC stage (S120), and when the layout does not satisfy the design rule (NG), the mask manufacturing method may proceed to operation S110 of performing the layout design for the main pattern and may again design a layout of the main pattern.

After the operation S120 of performing the integrated OPC, the mask manufacturing method according to an embodiment may perform OPC verification in operation S215. The OPC verification may denote an operation of verifying whether the basic OPC is appropriately performed in the integrated OPC stage. The OPC verification may be performed through, for example, optical rule check (ORC). The ORC may be performed by comparing a simulation contour and an original layout of a pattern. An operation of comparing the simulation contour and the original layout may use edge placement errors (EPEs) for detecting a difference between error positions.

When the basic OPC is satisfied with a set reference in the OPC verification (G), for example, when the simulation contour is within an error tolerance range, the mask manufacturing method may proceed to the operation S130 of delivering the MTO design data. On the other hand, when the basic OPC is not satisfied with the set reference in the OPC verification (NG), for example, when the simulation contour is outside the error tolerance range, the mask manufacturing method may proceed to the operation S120 of performing the integrated OPC. In proceeding to the operation S120 of performing the integrated OPC, parameters such as model calibration, OPC recipe, horizontal bias, and/or vertical bias may be corrected, and the basic OPC may be again performed.

FIG. 3 is a flowchart illustrating in detail the integrated OPC in the mask manufacturing method of FIG. 1. The details described above with reference to FIGS. 1 and 2 will be briefly described or is omitted.

Referring to FIG. 3, the operation S120 of performing the integrated OPC may include a layout structure analysis operation S121, a templates separation operation S123, a dummy pattern generation operation S125, an SRAF generation operation S127, and a basic OPC operation S129.

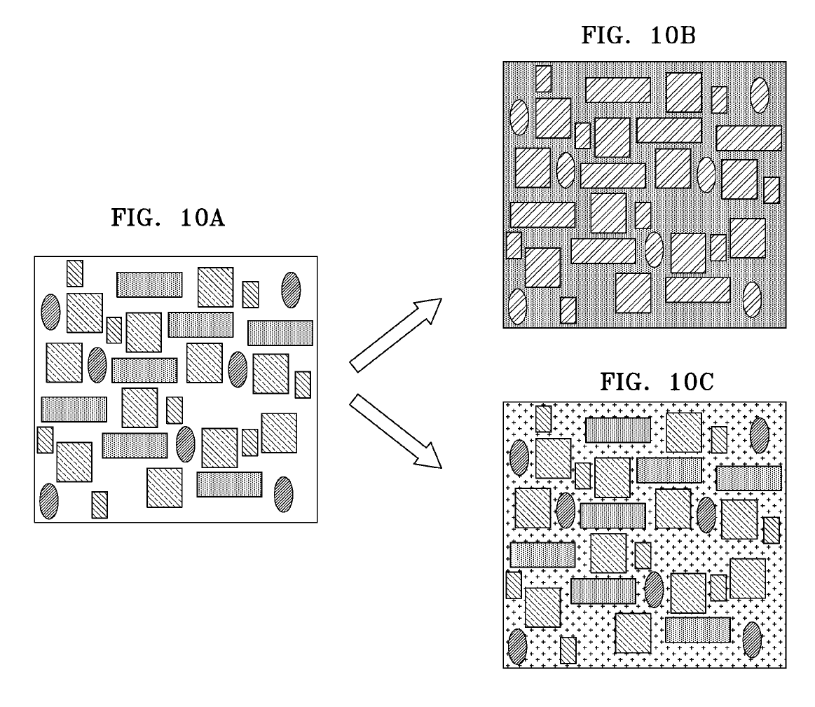

To provide a detailed description, first, when the layout design operation S110 for the main patterns is completed, a structure of a designed layout may be analyzed in operation S121. An operation of analyzing the layout may be a pre-operation of separating templates later, and the structure of the layout may be analyzed based on instances and influence ranges of the main patterns. Here, one instance may be used as a representative of patterns which have the same patterns and are repeated, and in designing the layout, the whole layout is easily designed by using an instance concept. For example, in FIG. 10 (a), different figures may represent respective instances. For example, an ellipse, a square, a laterally long tetragon, and a vertically long tetragon may represent the respective instances.

The influence range may denote a range which exerts an influence between patterns. For example, despite the same patterns, a result of a lithography process may vary according to whether another pattern is within the influence range. Therefore, the OPC may consider the influence range as well as structures of patterns itself.

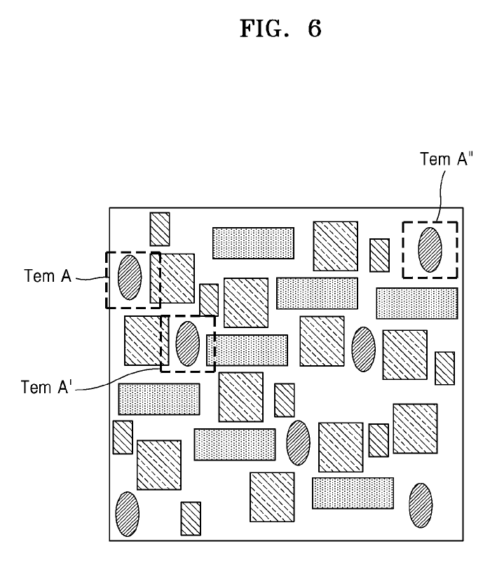

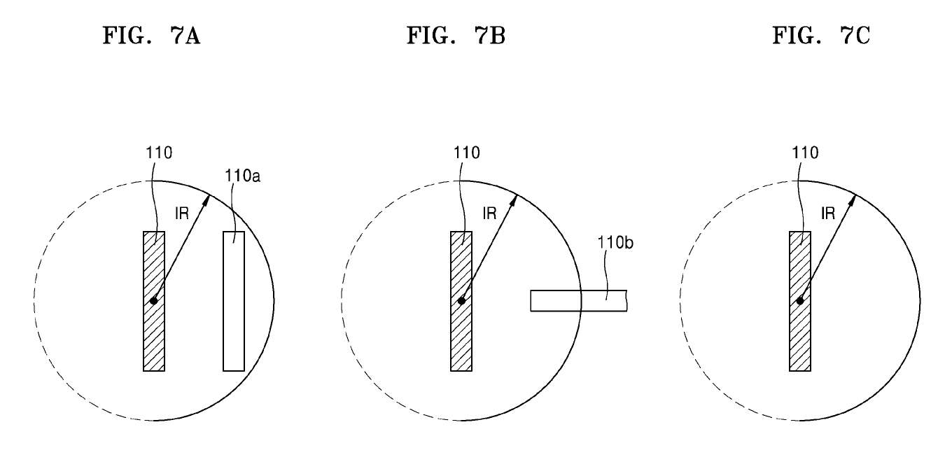

Subsequently, in operation S123, the templates may be separated from each other, based on the analysis of the structure of the layout. Here, the templates may each denote a concept of distinguishing patterns in the OPC stage and may denote a concept that includes an instance and an influence range. For example, the instance may be a concept of distinguishing patterns in the layout design stage and may be generated based on a structure difference between the patterns with no consideration of the influence range. However, the templates may each be generated in consideration of other patterns disposed within the influence range in addition to a structure of a pattern and may correspond to a basic unit for performing the basic OPC. A concept of a template will be described in detail with reference to FIGS. 6 and 7.

As the number of templates increases, a GDS data capacity and a runtime of the OPC increase exponentially. As a hierarchical instance of a designed layout is maintained, namely, as a high hierarchical structure of a layout is maintained, the number of templates may be reduced, and thus, the GDS data capacity and runtime of the OPC may be reduced. On the other hand, as a hierarchical instance of a layout is broken, namely, as a low hierarchical structure of a layout is maintained, the number of templates may increase, and thus, the GDS data capacity and runtime of the OPC may considerably increase.

After the templates are separated from each other, dummy patterns may be generated in operation S125. As described above, the dummy patterns may be generated for uniformly maintaining a density of patterns. However, in the integrated OPC according to the present embodiment, the dummy patterns may be respectively generated in the templates. In certain examples, dummy patterns may be generated for a whole layout before templates are separated from each other, but in the mask manufacturing method according to one embodiment, the templates may be separated from each other through the integrated OPC, and then, dummy patterns may be respectively generated in the templates. Therefore, dummy patterns may be generated in a state of maintaining a high hierarchical structure without a hierarchical structure being broken. The principle of generating dummy patterns in a template may be the same as the principle of generating an SRAF.

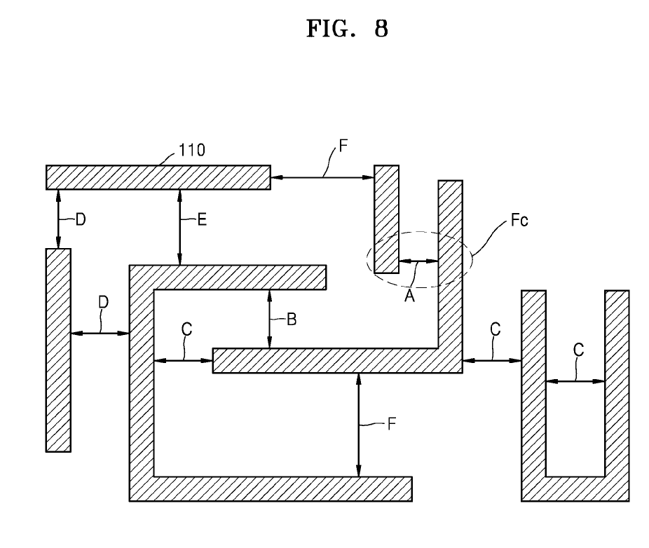

After the dummy patterns are generated, an SRAF may be generated in operation S127. The SRAF may be generated in units of one template. The principle of generating an SRAF will be described in detail with reference to FIGS. 8 and 9.

After the SRAF is generated, basic OPC may be performed in operation S129. The basic OPC has the same concept as that of general OPC. Because the basic OPC has been described above, its detailed description is not provided here. The basic OPC may be performed for each of templates. Accordingly, as the number of templates increases, a GDS data capacity and a runtime of the basic OPC may considerably increase. A dummy pattern generation operation, an SRAF generation operation, and the basic OPC may be performed for the same template.

When there are a plurality of same templates, the basic OPC may be performed for only one template, and a result of the basic OPC may be applied to the other same templates in the same way. Accordingly, the number of templates may be defined as the number of different templates. Also, an OPC area where OPC is performed may be defined as a total sum of different templates. The OPC area may represent a degree of compression of data and may be a criterion for estimating a runtime of the OPC. For example, as the OPC area is reduced, a runtime of the OPC may be reduced, and as the OPC area increases, a runtime of the OPC may increase.

Integrated OPC may be completed through the basic OPC, and then, the mask manufacturing method may proceed to the operation S130 of delivering the MTO design data.

As described above, in certain examples, dummy patterns may be generated through the DRC tool before templates are separated from each other, and the generation of the dummy patterns may become a main cause of breaking a hierarchical structure of a layout. In this case, the dummy pattern generating method increases the number of templates and exponentially increases a runtime and a GDS data capacity of OPC in an OPC stage. On the other hand, in the mask manufacturing method according to certain embodiments, the dummy patterns are not generated before separation of the templates. For example, dummy patterns may be generated in each of templates after separation of the templates by performing integrated OPC. Therefore, the incidence of an increase in number of templates is not large, and thus, a runtime and a GDS data capacity of OPC may not be increased in an OPC stage.

In FIG. 3, it is illustrated that the operation S121 of analyzing the structure of the layout is performed immediately after the operation S110 of designing the layout of the main pattern. However, as in the flowchart of FIG. 2, the operation S115 of performing the DRC may be performed before the operation S121 of analyzing the structure of the layout. Also, it is illustrated that the operation S130 of delivering the MTO design data is performed immediately after the operation S129 of performing the OPC. However, as in the flowchart of FIG. 2, the operation S215 of performing the OPC verification may be performed before the operation S130 of delivering the MTO design data.

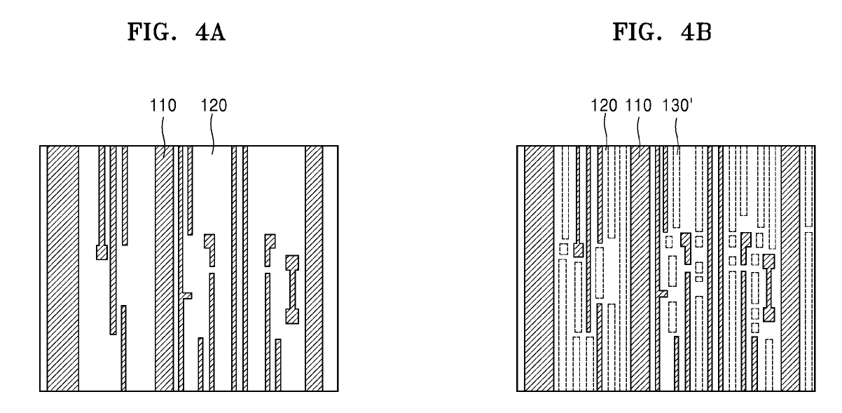

FIGS. 4A and 4B are layouts for describing the reason of forming a dummy pattern.

Referring to FIGS. 4A and 4B, FIG. 4A illustrates a designed layout of main patterns 110. The main patterns 110, for example, may correspond to metal wirings. However, the main patterns 110 are not limited to the metal wirings. A space 120 which is not hatched and is disposed near the main patterns 110 may correspond to a dielectric layer. However, the space 120 is not limited to the dielectric layer. For example, the space 120 may correspond to a semiconductor layer such as silicon or the like. As described above, due to the space 120 between the main patterns 110, a density of the main patterns 110 is non-uniform, causing a pattern defect in a lithography process. For example, both the space 120 and the main patterns 110 may not be uniform throughout the mask.

In order to prevent the pattern defect, as illustrated in FIG. 4B, dummy patterns 130′ illustrated as a dotted line in the space 120 may be formed. The dummy patterns 130′ may be formed of a material which is the same as or similar to that of the main patterns 110, and the main patterns 110 and the dummy patterns 130′ enhance uniformity of a whole pattern density. Accordingly, a pattern defect of a main pattern is prevented in the lithography process. Since the dummy patterns 130′ are irrelevant to an operation of a semiconductor device, the dummy patterns 130′ cannot be electrically connected to the main patterns 110.

FIGS. 5A and 5B are conceptual diagrams for describing a relationship of a hierarchical structure and a method of forming a dummy pattern.

Referring to FIGS. 5A and 5B, when dummy patterns D_{P} are not formed, templates TemA to TemC may be distinguished from and separated from each other and may each maintain a certain high hierarchical structure. As illustrated in FIG. 5A, when the dummy patterns D_{P} are formed in a boundary between the template TemA and the template TemB before the templates TemA to TemC are separated from each other, a hierarchical structure of each of the template TemA and the template TemB is broken. Also, since the dummy patterns D_{P} are generated, templates may no longer be separated into and distinguished from a template A (TemA) and a template B (TemB). As a result, after the dummy patterns D_{P} are generated, a higher number of new templates may be separated from and may be distinguished from one another, and the new templates may have a low hierarchical structure.

Moreover, as illustrated in FIG. 5B, when dummy patterns D_{PA} and D_{PB} are respectively formed in templates TemA and TemB after the templates TemA to TemC are separated from each other, the templates TemA and TemB may maintain a certain high hierarchical structure. For example, when a dummy pattern A (D_{PA}) is formed in a template A (TemA) and a dummy pattern B (D_{PB}) is formed in a template B (TemB), a hierarchical structure of each of the template A (TemA) and the dummy pattern B (D_{PB}) is not broken, or even though the hierarchical structure is broken, the hierarchal structure may be broken in only a corresponding template without affecting another template. In a template whose hierarchical structure has been broken, the basic OPC may be performed for a template itself including dummy patterns, based on the number of operations, or the template may be separated into new templates, the new templates may be distinguished from each other, and the basic OPC may be performed for the new templates.

For example, the incidence of an increase in number of templates and the incidence of an increase in runtime of the OPC may be minimized by generating dummy patterns after templates are separated from each other. As illustrated in FIG. 5A, a method of generating dummy patterns before separation of templates is shown, where dummy patterns are generated by using the DRC tool, and then templates are distinguished from each other, and then the OPC is performed. As illustrated in FIG. 5B, a method of generating dummy patterns after separation of templates corresponds to an operation of performing the integrated OPC in the mask manufacturing method according to an embodiment.

FIGS. 6 and 7A to 7C are conceptual diagrams for describing a concept of a template.

Referring to FIG. 6, a layout of main patterns is illustrated as being expressed as instances, and figures having the same structure and hatching may be one instance and may represent patterns having the same structure. For example, an ellipse, a square, a laterally long tetragon, and a vertically long tetragon may be instances which are distinguished from each other, and may represent patterns having structures which are distinguished from each other. In an operation of designing a layout of main patterns, since an instance maintains a high hierarchical structure, the instance may be referred to as a hierarchical instance.

Templates may be distinguished from and separated from each other in consideration of other main patterns which are located within an influence range. For example, templates TemA, TemA′ and TemA″ may have the same pattern structure corresponding to an ellipse, but since a pattern corresponding to another instance is located within the influence range illustrated as a dotted line, the templates TemA, TemA′ and TemA″ may be distinguished as different templates and may be treated as distinguishable templates from each other. Here, the another instance located within the influence range may denote all instances except its own instance. For example, in a first template TemA, a square instance may be located on the right within the influence range. Also, in a second template TemA′, a square instance may be located on the left within the influence range, and an instance having a laterally long tetragon may be located on the right within the influence range. Also, in a third template TemA″, no instance may be located within the influence range. Therefore, each of the first to third templates TemA, TemA′ and TemA″ may be distinguished as different templates and separated into different templates from each other.

Referring to FIGS. 7A to 7C, a shape of a first main pattern 110 may be changed in a lithography process according to whether second main patterns 110a and 110b are located within an influence range IR. For example, in a lithography process, the shape of the first main pattern 110 when the second main patterns 110a and 110b are located within the influence range IR as illustrated in FIGS. 7A and 7B may differ from that of the first main pattern 110 when no other main patterns are located within the influence range IR as illustrated in FIG. 7C.

When the second main patterns 110a and 110b are located within the influence range IR of the first main pattern 110 and shapes of the second main patterns 110a and 110b differ from each other, the shape of the first main pattern 110 may be changed. For example, in a lithography process, the shape of the first main pattern 110 when a whole portion of the second main pattern 110a is located within the influence range IR of the first main pattern 110 as illustrated in FIG. 7A may differ from that of the first main pattern 110 when a portion of the second main pattern 110a is located within the influence range IR of the first main pattern 110 as illustrated in FIG. 7B.

Therefore, in the OPC, templates may be distinguished from and separated from each other in consideration of the lithography process. For example, the templates may be distinguished from and separated from each other in consideration of a structure and an influence range of a main pattern, and the OPC may be performed for each of the separated templates.

The influence range IR, as illustrated in FIGS. 7A, 7B, and 7C, may be defined in a circular shape. However, the influence range IR is not limited to a circular shape. For example, an influence range may be implemented to appropriately represent a range which is affected by peripheral patterns in the lithography process. In this example, main patterns are within an influence range. However, the same or a similar influence may be exerted on dummy patterns within the influence range. For example, the shape of the first main patterns 110 may vary in the lithography process among cases when dummy patterns are located within the influence range IR instead of the second main patterns 110a and 110b, and when no dummy pattern is located within the influence range IR.

FIGS. 8 and 9 are layouts illustrating a method of generating a sub-resolution assist feature (SRAF).

When a layout of a main pattern 110 is designed as illustrated in FIG. 8, intervals A to F between main patterns may have different values. The intervals A to F may be measured and analyzed by using a manual or simulation program. Also, a threshold pitch may be identified from among the intervals A to F. For example, when a first interval A corresponds to the threshold pitch (i.e., a minimum interval and a line width), a feature F_{C} including the first interval A may correspond to the threshold pitch.

The intervals A to F between the main patterns may be measured and analyzed, and then, the arrangement positions, widths, lengths, and number of scattering bars (SBs) and a feature bias may be determined based on an interval therebetween according to guided estimation. The guided estimation may be provided through simulation software.

FIG. 9 illustrates, based on the principle of arranging SBs, a structure where SBs 112a to 112d are arranged for a main pattern 110. For example, when the main pattern 110 has a first width W1, first SBs 112a and third SBs 112c may be arranged to have a second width W2. Second SBs 112b and fourth SBs 112d may be arranged to have the second width W2. The first SBs 112a may have a same length. The third SBs 112c may have a same length. The lengths of the second SBs 112b may be different from each other. The lengths of the fourth SBs 112d may be different from each other. Here, the second width W2 may be less than a resolution of exposure equipment. The number, lengths, and widths of the SBs 112a to 112d may vary according to structures and arrangement intervals of the main pattern 110 and neighboring main patterns.

Moreover, serifs 114a to 114c may be respectively formed in a corner and ends of the main pattern 110. The serifs 114a to 114c may be arranged according to the principle similar to that of an SRAF. For example, a first serif 114a and a second serif 114b may have a third width W3, and a third serif 114c may have a fourth width W4. Here, the third width W3 and the fourth width W4 may be greater than the resolution of the exposure equipment. Due to a structural difference between (e.g., shapes of) the first and second serifs 114a and 114b, the first and second serifs 114a and 114b may be distinguished from the third serif 114c and may be referred to as a hammerhead.

In the mask manufacturing method according to the present embodiment, dummy patterns may be generated according to the principle which is the same as the principle of generating an SRAF. For example, guided estimation for the arrangement positions, widths, lengths, and number of dummy patterns and a feature bias may be set based on intervals between main patterns. Therefore, the intervals between the main patterns may be measured and analyzed, and then, the dummy patterns may be generated according to the set guided estimation. The guided estimation for arrangement of the main patterns may be implemented and provided by using the simulation software.

FIGS. 10A to 10C are a conceptual diagram illustrating a result obtained by applying a hierarchical dummy pattern generating method according to an embodiment and a result obtained by applying a dummy pattern generating method generating dummy patterns before defining templates.

Referring to FIGS. 10A to 10C, FIG. 10A illustrates a layout of main patterns expressed as hierarchical instances as described above with reference to FIG. 6. Here, a portion which is not hatched and is disposed between the hierarchical instances may denote a space. Also, in FIG. 10B, dummy patterns may be generated by using the DRC tool before templates are distinguished from and separated from each other, and then, a layout may be expressed as instances. In FIG. 10B, areas being hatched between the instances may denote that the dummy patterns are generated near the instances.

In FIG. 10A, instances (i.e., the hierarchical instances) may be clearly distinguished from each other through different hatchings. This may denote that the hierarchical instances maintain a high hierarchical structure. On the other hand, as shown in FIG. 10B, the instances may be illustrated as the same hatching. This may denote that the hierarchical structures of the instances are broken after the dummy patterns are generated, and thus, the instances have a low hierarchical structure. When input data of the OPC stage corresponds to a layout having a low hierarchical structure, the runtime and GDS data capacity of the OPC increase as described above.

FIG. 10C illustrates a structure of an embodiment. In this embodiment, dummy patterns are generated for each of templates after the templates are distinguished from and separated from each other through the integrated OPC, and the templates are again integrated and expressed as instances. As illustrated in FIG. 10C, the instances are illustrated as different hatchings as illustrated in FIG. 10A. This may denote that hierarchical structures of the instances are maintained as-is (e.g., as they were before generating dummy patterns). In FIG. 10C, areas between the instances are hatched, but are illustrated unlike the hatching of FIG. 10B. This may denote that the dummy patterns are generated and maintain a certain hierarchical structure. For example, the dummy patterns generated by the integrated OPC may have a semi-hierarchical structure. As described above, when input data of the OPC stage corresponds to a layout having a high hierarchical structure or a semi-hierarchical structure, the runtime and GDS data capacity of the OPC are considerably reduced.

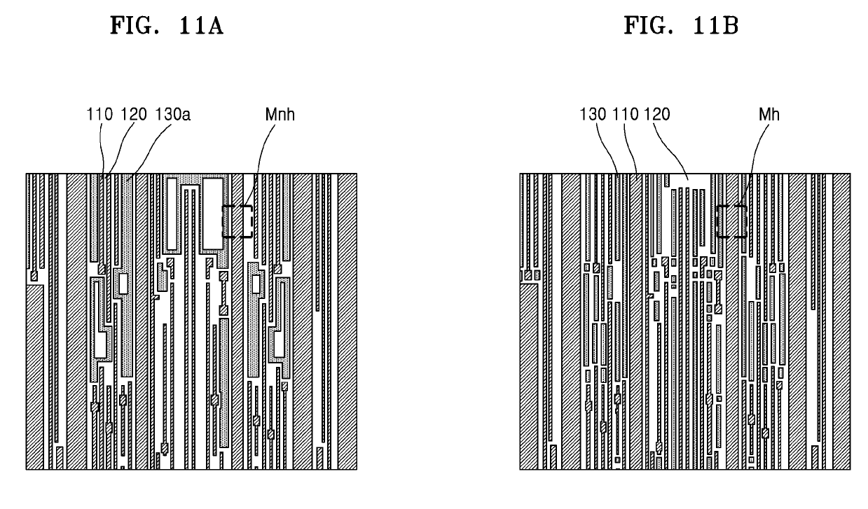

FIGS. 11A and 11B are a template illustrating a result obtained by applying a hierarchical dummy pattern generating method according to an embodiment and a result obtained by applying a dummy pattern generating method generating dummy patterns before defining templates.

Referring to FIGS. 11A and 11B, FIG. 11A illustrates a template including dummy patterns 130a. Since the dummy patterns 130a are generated, main patterns 110 and the dummy patterns 130a enhance the whole pattern density uniformity of the template. Here, a space 120 near the main patterns 110 may be changed according to the main patterns 110. For example, when the main patterns 110 correspond to a metal wiring layer, the space 120 may correspond to a dielectric layer.

In FIG. 11A, structures of the dummy patterns 130a may be complicated, and the main pattern 110 and the dummy patterns 130a may have a low hierarchical structure or a non-hierarchical structure. Also, the dummy patterns 130a may have a layout that has some problems for a lithography process, and a density of the dummy patterns 130a may be low in some areas. Therefore, image quality after the lithography process may be low.

On the other hand, FIG. 11B illustrates a template including dummy patterns 130 which are generated through the integrated OPC according to the present embodiment. Since the dummy patterns 130 are generated, main patterns 110 and the dummy patterns 130 enhance the whole pattern density uniformity of the template.

In FIG. 11B, structures of the dummy patterns 130 may be relatively simple. For example, the dummy patterns 130 may be formed in a line structure. Also, the main pattern 110 and the dummy patterns 130 may have a high hierarchical structure. Furthermore, the dummy patterns 130 may have a litho-friendly dummy layout for the lithography process and may have a high dummy pattern density. Therefore, image quality after the lithography process is very good.

For example, FIGS. 11A and 11B show patterns formed by the lithography process. Comparing main patterns Mnh and Mh within dotted squares, the main pattern Mnh of FIG. 11A has an asymmetric structure where the dummy patterns 130a are arranged only on the left of the main pattern 110, but the main pattern Mh of FIG. 11B has a symmetric structure where the dummy patterns 130 are arranged on both sides of the main pattern 110. Therefore, the main pattern Mh of FIG. 11B may be a better pattern structure for lithography process than the pattern Mnh, and the pattern Mh may have a better image shape after the lithography process than the pattern Mnh.

The following Table 1 shows results of a dummy pattern generating methods using integrated OPC according to the present embodiment and a reference example.

TABLE 1

| | OPC | | | | OPC | | | |
|---|---|---|---|---|---|---|---|---|
| | template | | OPC area | | runtime | | DB size | |
| | (×10,000) | | (mm²) | | (hours) | | (Gigabyte) | |
| | Case | | Case | | Case | | Case | Case |
| | 1 | Case 2 | 1 | Case 2 | 1 | Case 2 | 1 | 2 |
| Ref. | 83.3 | 3.1 | 69.5 | 30.0 | 18.5 | 13.8 | 15.2 | 9.7 |
| Int. | 43.5 | 1.7 | 42.3 | 12.8 | 9.8 | 5.8 | 8.6 | 2.7 |
| Imp. | 47.5 | 45.2 | 39.1 | 57.3 | 56.8 | 61.6 | 43.4 | 72.2 |
| (%) | | | | | | | | |

Here, Ref denotes a method of the reference example using non-integrated OPC. Non-integrated OPC defines templates after dummy pattern generation. Int. denotes a method according to the present embodiment using integrated OPC, and Imp. (%) denotes an improvement amount expressed as %. Also, OPC template denotes the number of templates, and OPC area denotes an area where the OPC is performed and may correspond to a sum of all templates. OPC runtime denotes a time for which the OPC is performed, and DB size denotes a size of a GDS data capacity. Here, Case 1 may correspond to a complicated circuit structure of a BEOL stage, and Case 2 may correspond to a simple circuit structure of an FEOL stage. Also, units may be the same in lengthwise items. For example, the unit of OPC templates may be 10,000, the unit of OPC area may be mm², the unit of OPC runtime may be hour, and the unit of DB size may be gigabyte (GB).

As seen in Table 1, it may be checked that since the mask manufacturing method according to the present embodiment performs the integrated OPC, the mask manufacturing method reduces an OPC runtime and a GDS data capacity by approximate 50% or more.

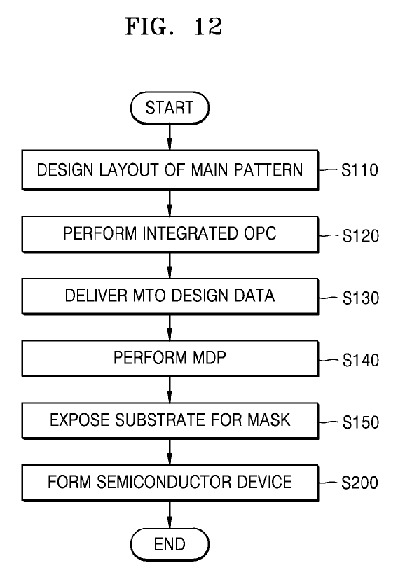

FIG. 12 is a flowchart of a semiconductor device manufacturing method according to an embodiment. The details described above with reference to FIGS. 1 to 3 will be briefly described or omitted.

Referring to FIG. 12, a mask may be manufactured by performing the processes described above with reference to FIGS. 1 to 3. For example, the mask may be manufactured by performing the operations from the operation S110 of designing a layout of a main pattern to the operation S150 of exposing a substrate for a mask.

When the mask has been manufactured, a semiconductor device is formed by performing various semiconductor manufacturing processes on a semiconductor substrate such as a wafer by using the manufactured mask, in operation S200. For reference, a process using the mask denotes a patterning process using a lithography process, and a desired pattern may be formed on a semiconductor substrate or a material layer through the patterning process using the mask.

The semiconductor manufacturing processes may include a deposition process, an etching process, an ion process, and a cleaning process. Here, the deposition process may include various material layer forming processes such as chemical vapor deposition (CVD), sputtering, and spin coating. The ion process may include processes such as ion injection, diffusion, and thermal treatment. The semiconductor manufacturing processes may include a packaging process, in which a semiconductor device is mounted on a printed circuit board (PCB) and is sealed by a sealant, and a test process of testing a semiconductor device or a package.

After the packaging process is completed, the semiconductor package may be mounted on a board, for example, printed circuit board to form an electronic device. For example the semiconductor package may be a component of an electronic device.

As described above, since the mask manufacturing method according to the embodiments includes the integrated OPC stage of simultaneously performing a dummy pattern generation operation and the basic OPC, thereby addressing a situation where a runtime and a GDS data capacity largely increase in a subsequent OPC stage because a dummy pattern is generated at a flat level by using the DRC tool. Therefore, the mask manufacturing method according to the embodiments considerably decreases a series of process (for example, a TAT of the OPC and the ORC) of manufacturing a mask after a layout of a mask pattern is designed, thereby considerably decreasing the time and cost of a mask manufacturing process and lowering the required performance of a system.

While various aspects of the inventive concept have been particularly shown and described with reference to exemplary embodiments thereof, it will be understood that various changes in form and details may be made therein without departing from the spirit and scope of the following claims.

What is claimed is:

1. A method comprising:
designing a layout of a main pattern;
performing integrated optical proximity correction (OPC) on the layout;
obtaining design data from the result of the integrated OPC;
delivering the design data as mask tape-out (MTO) design data;
preparing mask data, based on the MTO design data; and
exposing a substrate to form a mask, based on the mask data,
wherein the performing of the integrated OPC comprises generating a dummy pattern in a state of maintaining hierarchical structure.

2. The method of claim 1, wherein the performing of the integrated OPC comprises:
analyzing a structure of the layout;
separating templates, based on the analysis;
generating the dummy pattern after separating the templates;
generating a sub-resolution assist feature (SRAF); and
performing OPC on the templates.

3. The method of claim 2, wherein the dummy pattern is generated in a state of maintaining the hierarchical structure in each of the templates.

4. The method of claim 2, wherein the dummy pattern and the SRAF are generated in the same template.

5. The method of claim 2, wherein the templates are distinguished from and separated from each other, based on an influence range of the main pattern.

6. The method of claim 2, wherein
the main pattern is a pattern corresponding to a circuit pattern of a semiconductor device,
the dummy pattern is an auxiliary pattern for preventing a patterning error of the circuit pattern and is formed in the semiconductor device, and
the SRAF is an auxiliary pattern for compensating for an OPC deviation caused by a density difference between patterns and is not formed in the semiconductor device.

7. The method of claim 1, wherein the performing of the integrated OPC comprises receiving data corresponding to the layout, which does not include the dummy pattern.

8. The method of claim 1, further comprising: after the designing of the layout, performing a design rule check (DRC),
wherein the performing of the DRC comprises:
proceeding to the performing of the integrated OPC when a predetermined reference is satisfied; and
proceeding to the designing of the layout when the predetermined reference is not satisfied.

9. The method of claim 1, further comprising: after the performing of the integrated OPC, performing OPC verification,
wherein the performing of the OPC verification comprises:
proceeding to the delivering of the design data as the MTO design data when a predetermined reference is satisfied; and
proceeding to the performing of the integrated OPC when the predetermined reference is not satisfied.

10. The method of claim 1, further comprising:
exposing a semiconductor substrate using the mask to form a semiconductor device.

11. A method of manufacturing a semiconductor device, the method comprising:
designing a layout of a main pattern;
receiving data corresponding to the layout;
performing integrated optical proximity correction (OPC) including generating a dummy pattern in a state of maintaining a hierarchical structure and generating design data;
delivering the design data as mask tape-out (MTO) design data;
preparing mask data, based on the MTO design data;
exposing a substrate to form a mask, based on the mask data; and
forming a semiconductor device through a lithography process using the mask.

12. The method of claim 11, wherein the performing of the integrated OPC comprises:
analyzing a structure of the layout to separate templates;
generating the dummy pattern and a sub-resolution assist feature (SRAF) in each of the templates; and
performing OPC on the templates.

13. The method of claim 12, wherein the dummy pattern and the SRAF are generated in the same template.

14. The method of claim 11, further comprising:
after the designing of the layout, performing design rule check (DRC); and
after the performing of the integrated OPC, performing OPC verification,
wherein
the performing of the DRC comprises proceeding to the performing of the integrated OPC or the designing of the layout according to whether a predetermined reference is satisfied, and
the performing of the OPC verification comprises proceeding to the delivering of the design data as the MTO design data or the performing of the integrated OPC according to whether the predetermined reference is satisfied.

15. A method, comprising;
designing a layout of main patterns of a mask;
determining the layout into a plurality of templates based on the structure of the layout;
generating dummy patterns in the respective templates;
performing optical proximity correction in the patterns of the respective templates;
delivering mask tape-out design data based on the result of the optical proximity correction; and
forming a photomask with the mask tape-out design data.

16. The method of claim 15, further comprising:
exposing a substrate using the photomask to form a photoresist pattern on the substrate;
etching the substrate using the photo resist pattern as an etching mask; and
dividing the substrate into a plurality of chips.

17. The method of claim 16, further comprising:
forming a semiconductor package with a first chip of the plurality of chips; and
mounting the package on a board to form an electronic device.

18. The method of claim 15, further comprising:
generating sub resolution assist features in the respective templates before performing the optical proximity correction.

19. The method of claim 15, further comprising:
performing a design rule check before the determining the layout into the plurality of templates.

20. The method of claim 15, wherein the determining the layout into the plurality of templates includes considering an influence range between adjacent patterns.
